(19) United States
(12) Patent Application Publication
(10) Pub. No.: US 2012/0043116 A1
(43) Pub. Date: Feb. 23, 2012

(54) Interconnection Structure Of Interposer With Low CTE And Packaging Component Having The Same

(75) Inventors: Hyun Tae Kim, Suwon-si (KR); Tae Sang Park, Seoul (KR); Young Jun Moon, Hwaseong-si (KR); Soon Min Hong, Seoul (KR)

(73) Assignee: SAMSUNG ELECTRONICS CO., LTD., Suwon-si (KR)

(21) Appl. No.: 13/211,596

(22) Filed: Aug. 17, 2011

(30) Foreign Application Priority Data
Aug. 23, 2010 (KR) 10-2010-0081685

(51) Int. Cl. H05K 1/11; H05K 1/02

(52) U.S. Cl. 174/254; 174/255

(57) ABSTRACT

Disclosed herein are printed circuit board assemblies made of a brittle material such as silicon, glass or ceramic and provided with a connector to electrically connect the same to an external connection member, and a method for molding the printed circuit board assembly wherein the printed circuit board assembly is molded by applying a polymer resin thereto to impart hardness to the printed circuit board assembly, and an electrode terminal to connect the same to the external connection member is exposed to the outside. Disclosed herein is also an interconnection structure of an interposer, the interconnection structure electrically connected to a main printed circuit board (PCB) through a solder joint is interposed between the interposer and the solder joint to prevent or reduce concentration of stress on the solder joint caused by differences in coefficients thermal expansion between the interposer and the main PCB.

### CROSS-REFERENCE TO RELATED APPLICATION(S)

This application claims priority under 35 U.S.C. §119 to Korean Patent Application No. 2010-0081685, filed on Aug. 23, 2010 in the Korean Intellectual Property Office (KIPO), the disclosure of which is incorporated herein by reference in its entirety.

### BACKGROUND

1. Field

Example embodiments relate to an interconnection structure to connect an interposer to a main printed circuit board in a packaging component using an interposer having a low coefficient of thermal expansion and a packaging component including the same.

2. Description of the Related Art

Packaging components using an interposer having a low coefficient of thermal expansion such as silicon (Si), glass or ceramics are often mounted in an organic main printed circuit board (PCB).

Surface mount technology (SMT) is used to mount packaging components on main printed circuit boards. In accordance with the SMT method, a solder ball formed in packaging components and a solder paste printed on the main printed circuit board reflow to form a solder joint to connect the packaging component to the main PCB.

In the case where the solder joint thus formed is exposed to thermal shock, when stress is concentrated on the solder joint due to differences in coefficients of thermal expansion between the interposer and the organic main PCB and the stress is repeatedly applied to the solder joint due to continuous thermal shock, fatigue fracture may occur.

### SUMMARY

In example embodiments, an interconnection structure is provided to reduce or prevent concentration of stress on a solder joint caused by differences in coefficients of thermal expansion between an interposer and an organic main printed circuit board. In a case where packaging components using an interposer having a low coefficient of thermal expansion are mounted on an organic main PCB, a packaging component including the same is provided.

Additional aspects of example embodiments will be set forth in part in the description which follows and, in part, will be obvious from the description, or may be learned by practice of example embodiments.

In accordance with example embodiments, an interconnection structure of an interposer is provided. In example embodiments, the interconnection structure is electrically connected to a main printed circuit board (PCB) through a solder joint. In example embodiments the interposer is comprised of one of silicon (Si), glass, and a ceramic, and the interconnection structure is between the interposer and the solder joint to reduce concentration of stress on the solder joint caused by differences in coefficients of thermal expansion between the interposer and the main PCB.

In accordance with example embodiments, an interconnection structure of an interposer is provided. In example embodiments, the interconnection structure may be electrically connected to a main printed circuit board. Further, the interposer may be comprised of one of silicon, a glass, and a ceramic. In example embodiments, a connector electrically connecting the interposer to the main printed circuit board may be between the interposer and the main printed circuit board.

In accordance with example embodiments, a packaging component is provided. In example embodiments, the packaging component may be obtained by coating an interposer electrically connected to a main printed circuit board (PCB) through a solder joint and an electronic component on the interposer with a resin and molding the coating. In example embodiments, the interposer is comprised of one of silicon, a glass, and a ceramic. Furthermore, the packaging component may include an interconnection structure to reduce concentration of stress on the solder joint caused by differences in coefficients of thermal expansion between the interposer and the main PCB.

In accordance with example embodiments, a packaging component is provided. In example embodiments, the packaging component may be obtained by coating an interposer electrically connected to a main printed circuit board (PCB) through a solder joint and an electronic component on the interposer with a resin and molding the coating. In example embodiments, the interposer may be comprised of one of silicon (Si), a glass, and a ceramic. Furthermore, the packaging component may include a connector configured to electrically connect the interposer to the main PCB. Furthermore, an electrode terminal configured to connect the connector to the main PCB may be exposed outside of the resin.

In accordance with one aspect of example embodiments, provided is an interconnection structure of an interposer electrically connected to a main printed circuit board (PCB) through a solder joint, wherein the interposer is made of silicon (Si), a glass or a ceramic, and an interconnection structure is interposed between the interposer and the solder joint to prevent or reduce concentration of stress on the solder joint caused by differences in coefficients of thermal expansion between the interposer and the main PCB.

The interconnection structure may include a rigid printed circuit board (PCB).

The interposer may be wire-bonded to the rigid printed circuit board to electrically connect the interposer to the rigid printed circuit board.

Alternatively, a through silicon via (TSV) may be formed on the interposer to electrically connect the interposer to the rigid printed circuit board.

Alternatively, the interconnection structure may further include a flexible PCB to electrically connect the interposer to the rigid printed circuit board.

In accordance with another aspect of example embodiments, provided is an interconnection structure of an interposer electrically connected to a main printed circuit board wherein the interposer is made of silicon, a glass or ceramic, and wherein a connector to electrically connect the interposer to the main printed circuit board is interposed between the interposer and the main printed circuit board.

A flexible PCB may be interposed between the interposer and the connector to electrically connect the interposer to the connector.

Alternatively, a lead frame may be interposed between the interposer and the connector to electrically connect the interposer to the connector.

Alternatively, the interposer may be wire-bonded to the connector to electrically connect the interposer to the connector.

In accordance with another aspect of example embodiments, provided is a packaging component obtained by coating an interposer electrically connected to a main printed circuit board (PCB) through a solder joint and an electronic component mounted on the interposer with a resin and molding the coating, wherein the interposer is made of silicon (Si), a glass or a ceramic, and the packaging component comprises an interconnection structure to prevent concentration of stress on the solder joint caused by the differences in coefficient of thermal expansion between the interposer and the main printed circuit board.

The interconnection structure may include a rigid printed circuit board.

The interposer may be wire-bonded to the rigid printed circuit board to electrically connect the interposer to the rigid printed circuit board.

Alternatively, a through silicon via (TSV) may be formed on the interposer to electrically connect the interposer to the rigid printed circuit board.

Alternatively, the packaging component may further include a flexible PCB to electrically connect the interposer to the rigid printed circuit board.

In accordance with another aspect of example embodiments, provided is a packaging component obtained by coating an interposer electrically connected to a main printed circuit board (PCB) through a solder joint and an electronic component mounted on the interposer with a resin and molding the coating, wherein the interposer is made of silicon (Si), a glass or a ceramic, wherein the packaging component comprises a connector to electrically connect the interposer to the main printed circuit board, wherein an electrode terminal to connect the main printed circuit board of the connector is exposed to the outside of the resin.

A flexible PCB may be interposed between the interposer and the connector to electrically connect the interposer to the connector.

Alternatively, a lead frame may be interposed between the interposer and the connector to electrically connect the interposer to the connector.

Alternatively, the interposer may be wire-bonded to the connector to electrically connect the interposer to the connector.

### BRIEF DESCRIPTION OF THE DRAWINGS

These and/or other aspects of example embodiments will become apparent and more readily appreciated from the following description of the embodiments, taken in conjunction with the accompanying drawings of which:

FIG. 1 is a view illustrating an interconnection structure of an interposer according to example embodiments;

FIG. 2 is a view illustrating an interconnection structure of an interposer according to example embodiments;

FIG. 3 is a view illustrating an interconnection structure of an interposer according to example embodiments; and

FIG. 4 is a view illustrating an interconnection structure of an interposer according to example embodiments.

### DETAILED DESCRIPTION

Example embodiments will be described more fully hereinafter with reference to the accompanying drawings, in which example embodiments are shown. The present invention may, however, be embodied in many different forms and should not be construed as limited to example embodiments as set forth herein. Rather, example embodiments are provided so that this disclosure will be thorough and complete, and will fully convey the scope of the present invention to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers that may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of example embodiments.

Spatially relative terms, such as “beneath,”. “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing example embodiments only and is not intended to be limiting of the present invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized example embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Reference will now be made in detail to example embodiments as illustrated in the accompanying drawings, wherein like reference numerals refer to like elements throughout.

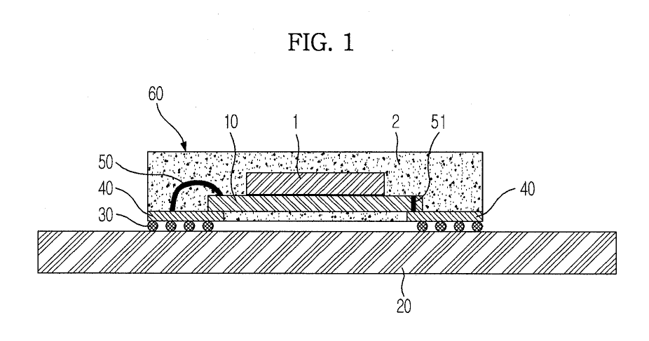

FIG. 1 is a view illustrating an interconnection structure of an interposer according to example embodiments.

Referring to FIG. 1, a packaging component 60 in accordance with example embodiments may include the interconnection structure of an interposer 10. For example, the package component 60 may include an electronic component 1, an interposer 10, a rigid printed circuit board 40 (referred to as a “rigid PCB”) and an epoxy mold resin 2. In example embodiments, the packaging component 60 may be mounted on a main printed circuit board 20 via a solder joint 30.

The electronic component 1 may be mounted on the interposer 10 by wire bonding, tape automated bonding (TAB), or by using a surface mounted technology (SMT), however, the invention is not limited to these technologies or methods.

The rigid PCB 40 may be an interconnection structure that may reduce stress applied to the solder joint 30 due to a difference in thermal expansion coefficients between the interposer 10 having a relatively low coefficient of thermal expansion (4 to 12 ppm) and the main printed circuit board 20. In example embodiments, the interposer may be comprised of, but not limited to, silicon, glass, or ceramic. The rigid PCB 40 may be made of a material having a thermal expansion coefficient comparable to the main PCB 20 to prevent or reduce concentration of stress due to differences in the coefficients of thermal expansion between the rigid PCB 40 and the main PCB 20. In example embodiments, the rigid PCB 40 may be arranged at the outer bottom of the interposer 10 in a region provided between the interposer 10 and the solder joint 30.

The rigid PCB 40 may be electrically connected to the interposer 10 by wire-bonding the rigid PCB 40 to the interposer 10 resulting in a wire 50 forming the connection. Alternatively, the rigid PCB 40 may be electrically connected to the interposer 10 by forming a through silicon via 51 (TSV) through the interposer 10.

The rigid PCB 40 may be electrically connected to the interposer 10 as mentioned above, and the electronic component 1 provided interposer 10 and the rigid PCB 40 may be coated with an epoxy mold resin 2 and molded to obtain a packaging component 60.

The packaging component 60 thus obtained may be mounted on the main PCB 20. In example embodiments, the main PCB 20 may be made of an organic material and the packaging component may be mounted on the main PCB 20 by an SMT method using the solder joint 30. In example embodiments, the rigid PCB 40 and the main PCB 20, each of which is connected to the solder joint 30, may have similar coefficients of thermal expansion, thus stress may be prevented or reduced from being concentrated on the solder joint 30.

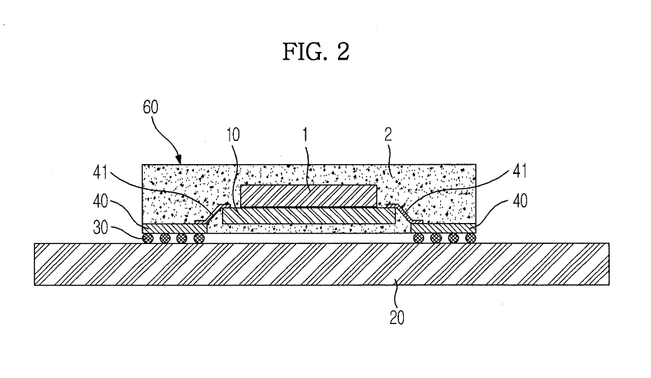

FIG. 2 is a view illustrating an interconnection structure of an interposer according to example embodiments.

FIG. 2 illustrates a packaging component 60 that may include the interconnection structure of an interposer 10. The packaging component 60 illustrated in FIG. 2 is similar to the packaging component 60 illustrated in FIG. 1. Thus, like components will not be discussed for the sake of brevity. Unlike the packaging component 60 of FIG. 1, the packaging component 60 illustrated in FIG. 2 includes a flexible printed circuit board 41 (flexible PCB) to electrically connect the interposer 10 to the rigid PCB 40.

In example embodiments, the flexible PCB 41 may be adhered to an area between the interposer 10 and the rigid PCB 40 and may be arranged on the outer top of the interposer 10 to electrically connect the interposer 10 to the rigid PCB 40. Although FIG. 2 illustrates the flexible PCB 41 as being attached to a top of the interposer 10, example embodiments are not limited thereto as the flexible PCB 41 may alternatively be connected to a bottom of the interposer 10. Similarly, although the flexible PCB 41 is illustrated as being connected to a top surface of the rigid PCB 40, example embodiments are not limited thereto as the flexible PCB 41 may be attached to a bottom surface of the rigid PCB 40

In example embodiments, the electronic component-mounted interposer 10 and the rigid PCB 40, as illustrated in FIG. 2, may be coated with an epoxy mold resin 2 and molded to obtain the packaging component 60, and the packaging component 60 may be mounted on the main PCB 20 using the solder joint 30.

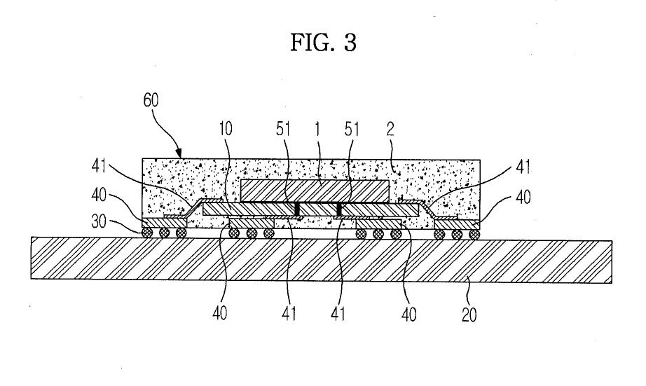

FIG. 3 is a view illustrating an interconnection structure of an interposer according to example embodiments.

Referring to FIG. 3, a packaging component 60 according to example embodiments may include the interconnection structure of an interposer 10. For example, the packaging component 60 may include an electronic component 1, an interposer 10, a rigid PCB 40, a flexible PCB 41 and an epoxy mold resin 2, and the rigid PCB 40 may be arranged on the outer bottom and a central bottom of the interposer 10. In example embodiment the flexible PCB 41 may be attached to a top of the interposer 10 and may extend to a top of the rigid PCB 40 as shown in FIG. 3, however, example embodiments are not limited thereto as the flexible PCB 41 may attach to a bottom of the interposer 10 and a bottom of the rigid PCB 40. Furthermore, as shown in FIG. 3, the flexible PCB 41 may be arranged between a central portion of the rigid PCB 40 and the central bottom of the interposer 10.

In example embodiments, a through silicon via 51 may be formed on or through the interposer 10 to electrically connect the interposer 10 to the flexible PCB 41 arranged on the central bottom of the interposer 10.

In example embodiments, as shown in FIG. 3, the electronic component 1 provided with the interposer 10, the rigid PCB 40, and the flexible PCB 41, may be coated with an epoxy mold resin 2 and molded to obtain a packaging component 60, and the packaging component 60 may be mounted on the main PCB 20 using the solder joint 30.

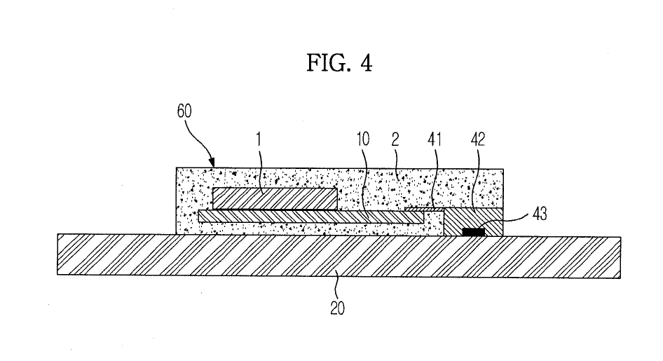

FIG. 4 is a view illustrating an interconnection structure of an interposer according to example embodiments.

Referring to FIG. 4, the packaging component 60 according to example embodiments may include an electronic component 1, an interposer 10, a flexible PCB 41, and a connector 42 configured to connect to a main PCB 20.

As shown in FIG. 4, the packaging component 60 may be connected to the main PCB 20 via the connector 42.

The interconnection structure of the interposer 10 according to example embodiments or the packaging component 60 using the same is not provided with a solder joint between the interposer 10 and the main PCB 20, thus eliminating the risk of stress concentration and fatigue fracture of the solder joint due to differences in coefficients of thermal expansion between the interposer 10 and the main PCB 20.

The connector 42 may include two electrode terminals. One (not shown) of the electrode terminals may be connected to the interposer 10 via the flexible PCB 41 and the other 43 may be exposed to the outside of the packaging component 60 and may be configured to connect to the main PCB 20.

In example embodiments, the flexible PCB 41 may be used to electrically connect the connector 42 to the interposer 10. Although not illustrated, the connector 42 may be connected to the interposer 10 by wire-bonding or by interposing a lead frame between the connector 42 and the interposer 10.

As apparent from the above discussion, the connector 42 may be included to connect the interposer 10 of the packaging component 60 to the main printed circuit board 20, and the packaging component 60 may thus be readily inserted into or separated from the main printed circuit board 20 of apparatuses, for example, mobile phones.

The interconnection structure of the interposer according to example embodiments may include a separate connection structure interposed between the interposer and the solder joint, thus stress may be reduced or prevented from being applied to the solder joint, thus fatigue fracture of the solder joint caused by repeated thermal shock may be reduced or prevented. Alternatively, the interconnection structure may use a connector, instead of the solder joint, to connect the interposer and the main PCB, thus thermal shock may be reduced or eliminated by virtue of the connector.

Although example embodiments have been shown and described, it would be appreciated by those skilled in the art that changes may be made in example embodiments without departing from the principles and spirit of the invention, the scope of which is defined in the claims and their equivalents.

What is claimed is:

1. An interconnection structure of an interposer electrically connected to a main printed circuit board (PCB) through a solder joint, wherein
the interposer is comprised of one of silicon (Si), glass, and a ceramic, and
the interconnection structure is between the interposer and the solder joint to reduce concentration of stress on the solder joint caused by differences in coefficients of thermal expansion between the interposer and the main PCB.

2. The interconnection structure according to claim 1, wherein the interconnection structure comprises a rigid printed circuit board (PCB).

3. The interconnection structure according to claim 2, wherein the interposer is wire-bonded to the rigid printed circuit board to electrically connect the interposer to the rigid printed circuit board.

4. The interconnection structure according to claim 2, wherein a through silicon via (TSV) is formed on the interposer to electrically connect the interposer to the rigid printed circuit board.

5. The interconnection structure according to claim 2, further comprising:
a flexible PCB electrically connecting the interposer to the rigid printed circuit board.

6. An interconnection structure of an interposer electrically connected to a main printed circuit board, wherein
the interposer is comprised of one of silicon, a glass, and a ceramic, and
a connector electrically connecting the interposer to the main printed circuit board is between the interposer and the main printed circuit board.

7. The interconnection structure according to claim 6, wherein a flexible PCB is between the interposer and the connector to electrically connect the interposer to the connector.

8. The interconnection structure according to claim 6, wherein a lead frame is between the interposer and the connector to electrically connect the interposer to the connector.

9. The interconnection structure according to claim 6, wherein the interposer is wire-bonded to the connector to electrically connect the interposer to the connector.

10. A packaging component obtained by coating an interposer electrically connected to a main printed circuit board (PCB) through a solder joint and an electronic component on the interposer with a resin and molding the coating, wherein
the interposer is comprised of one of silicon, a glass, and a ceramic, and
the packaging component includes an interconnection structure to reduce concentration of stress on the solder joint caused by differences in coefficients of thermal expansion between the interposer and the main PCB.

11. The packaging component according to claim 10, wherein the interconnection structure includes a rigid printed circuit board.

12. The packaging component according to claim 11, wherein the interposer is wire-bonded to the rigid printed circuit board to electrically connect the interposer to the rigid printed circuit board.

13. The packaging component according to claim 11, wherein a through silicon via (TSV) is on the interposer to electrically connect the interposer to the rigid printed circuit board.

14. The packaging component according to claim 11, further comprising:
a flexible PCB electrically connecting the interposer to the rigid printed circuit board.

15. A packaging component obtained by coating an interposer electrically connected to a main printed circuit board (PCB) through a solder joint and an electronic component on the interposer with a resin and molding the coating, wherein
the interposer is comprised of one of silicon (Si), a glass, and a ceramic,
the packaging component includes a connector configured to electrically connect the interposer to the main PCB, and
an electrode terminal configured to connect the connector to the main PCB is exposed outside of the resin.

16. The packaging component according to claim 15, wherein a flexible PCB is between the interposer and the connector and the flexible PCB electrically connects the interposer to the connector.

17. The packaging component according to claim 15, wherein a lead frame is between the interposer and the connector and the lead frame electrically connects the interposer to the connector.

18. The packaging component according to claim 15, wherein the interposer is wire-bonded to the connector to electrically connect the interposer to the connector.
